(19) United States
(12) Patent Application Publication
(10) Pub. No.: US 2025/0258210 A1
(43) Pub. Date: Aug. 14, 2025

(54) BANDWIDTH TUNABLE RYDBERG RADIO FREQUENCY DETECTOR

(71) Applicants: Eric Magnuson Bottomley, Broomfield, CO (US); John Mason Guthrie, Superior, CO (US); Shane Verploegh, Boulder, CO (US); Seth Charles Caliga, Lafayette, CO (US)

(72) Inventors: Eric Magnuson Bottomley, Broomfield, CO (US); John Mason Guthrie, Superior, CO (US); Shane Verploegh, Boulder, CO (US); Seth Charles Caliga, Lafayette, CO (US)

(21) Appl. No.: 19/049,309

(22) Filed: Feb. 10, 2025

Related U.S. Application Data
(60) Provisional application No. 63/551,951, filed on Feb. 9, 2024.

(51) Int. Cl. G01R 29/08

(52) U.S. Cl. CPC G01R 29/0885

(57) ABSTRACT

A method for RF sensing using a quantum sensor includes establishing an operational mode from at least two available operational modes, the two available operational modes where the first excitation mode has a narrower RF signal detection bandwidth. The method further generates, using laser sources having optical excitation parameters for the established operational mode, optical excitation of an atomic species. The method further detects an optical signal from the atomic species corresponding to an optical signal type associated with the established operational mode. The optical signal is elicited in response to an incident RF signal falling within an RF detection bandwidth corresponding to the established operational mode. In this method, the each first operational mode comprises a respective excitation mode and a respective optical signal type being produced in response to electromagnetically-induced transparency associated with the incident RF signal, or in response to an ensemble effect in the atomic species.

### PRIORITY

This application claims the benefit of priority to U.S. Provisional Patent Application Ser. No. 63/551,951, filed Feb. 9, 2024, which is incorporated by reference herein in its entirety.

### BACKGROUND

Radio frequency (RF) sensing is a technique used to detect and measure RF signals for various applications, such as communication systems, navigation, and environmental monitoring. RF sensors can be designed to detect signals across a wide range of frequencies and intensities.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a flow diagram for a method of radio frequency (RF) sensing.

FIG. 2 illustrates two excitation schemes for quantum RF sensing of an RF field.

FIG. 3 illustrates photodiode signals of electromagnetically induced transparency (EIT) and superradiant regimes across coupling laser detunings.

FIG. 4 illustrates bandwidth comparison of two modes of operating a quantum RF sensor.

FIG. 5 illustrates optical spectra for superradiant and non-superradiant regimes.

FIG. 6 illustrates a Rydberg radio frequency system including a modular chassis.

FIG. 7 illustrates a backend architecture diagram showing interconnected modules.

FIG. 8 illustrates vapor cell and sensor componentry.

### DETAILED DESCRIPTION

A quantum radio frequency (RF) sensor can provide RF detection through RF-optical transduction. A quantum RF sensor can be used in one of two operational modes, where a first operational mode has a narrow bandwidth, and a second operational mode has a broader bandwidth than the first operational mode. The sensor can be tuned to operate in a selected one of the two operational modes.

In particular, an atomic vapor can be excited using optical fields to establish an electromagnetically induced transparency/absorption (EIT/A) condition. Note that, electromagnetically induced transparency (EIT) and electromagnetically induced absorption (EIA) are both phenomena related to resonant changes in atomic absorption due to coherent interaction with incident optical radiation. References throughout the specification to either EIT or EIA can be understood to additionally include both EIT and EIA phenomena. Simultaneously, fluorescence is emitted as atoms decay from the Rydberg state, which may be measured by a detector. The presence of an incident RF field causes a resonance peak to be split (e.g., exhibit Autler-Townes splitting), which can be observed by scanning a probe laser wavelength through a wavelength range corresponding to the EIT or Rydberg fluorescence condition.

In an example, narrow bandwidth operation may occur with Rydberg states in the atomic vapor decaying individually. The bandwidth response of the EIT or fluorescence signal to incident RF fields can be narrow. In an example, an operational state may be established in Rydberg RF sensing systems where atoms exhibit collective decay behavior, characterized by increased optical light output and broader instantaneous bandwidth compared to EIT operation. The collective decay regime may be established through adjustment of optical excitation parameters including beam size, probe laser detuning, and optical power levels, enabling reception of broadband RF signals. Under various conditions, the collective decay may be attributed to superradiance behavior or ionization behavior. It can be understood that references to the collective decay which are termed “superradiance” behavior throughout can be interchanged with “ionization” behavior.

By controlling the operating regime of the quantum RF sensor, it is possible to operate using a selected sensing mode, such as selecting between the individual (atomic) decay behavior and the collective decay regime. In the individual decay mode, the quantum RF sensor can operate using a very narrow instantaneous detection bandwidth (iBW) mode with high sensitivity, providing out-of-band noise/interference rejection. By contrast, in the collective decay mode, the sensor can operate in a broad detection iBW mode for rapid spectrum search or signal ingestion.

Various parameters may be used to establish a respective operational mode. For example, one parameter is the excitation beam size. Modifying the excitation beam size may increase or decrease a volume of atoms which increases or decreases, respectively, the cooperativity (e.g., ensemble behavior) of the sensor. Another parameter can involve detuning the probe laser, e.g., which may include using a nominal wavelength aligned with the D2 line for Rubidium atoms. Additionally, an output power of various optical lasers or local oscillators (e.g., for RF heterodyne detection) can be increased to establish detection operation using the collective decay regime. As an illustration, an enhanced laser output power may be used to increase a total number of populated atoms in the Rydberg state for cooperativity.

The parameters that drive the transition from an individual atomic decay base-detection to collective decay-based detection, and back, may be software or firmware selectable. As an example, a system may include a software-controlled or firmware-controlled quantum RF sensing configuration capable of switching between two sensing modes.

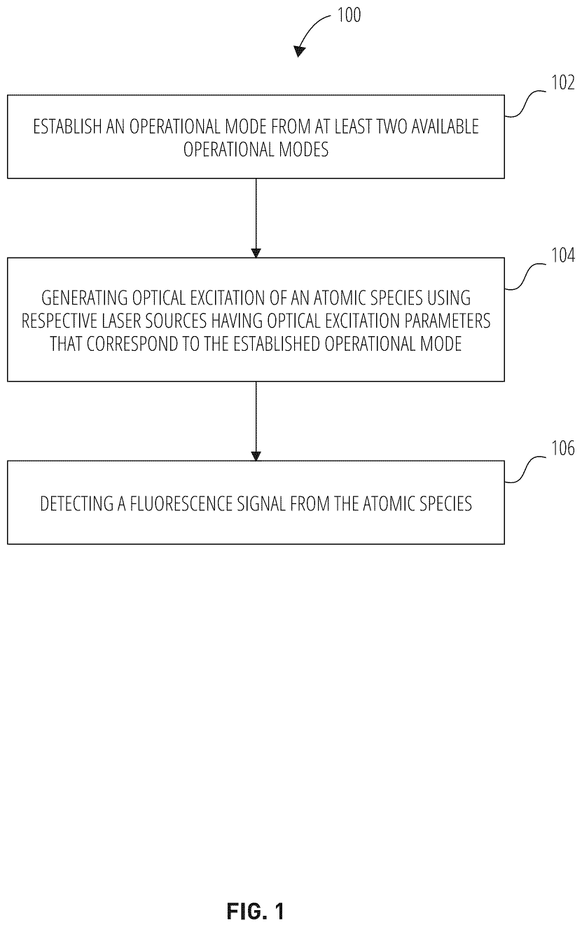

FIG. 1 illustrates a flow diagram for a technique, such as a machine-implemented or machine-controlled method 100 for RF sensing.

Although the example routine depicts a particular sequence of operations, the sequence may be altered without departing from the scope of the present disclosure. For example, some of the operations depicted may be performed in parallel or in a different sequence that does not materially affect the function of the routine. In other examples, different components of an example device or system that implements the routine may perform functions at substantially the same time or in a specific sequence.

At 102, the method 100 includes establishing an operational mode from at least two available operational modes, the two available operational modes corresponding to different RF detection bandwidths.

For example, the at least two available operational modes can include a first operational mode and a second operational mode. The first operational mode can include a first excitation mode and a first optical signal type being produced in response to electromagnetically-induced transparency (EIT) associated with the incident RF signal. In an example, the second operational mode comprises a second excitation mode and a second optical signal type being produced in response to an ensemble effect in the atomic species. In an example, the first optical signal type of the first excitation mode corresponds to a narrower RF signal detection bandwidth than the second optical signal type of the second excitation mode.

At 104, in an example, the method 100 includes generating, using respective laser sources having optical excitation parameters that correspond to the established operational mode, optical excitation of an atomic species.

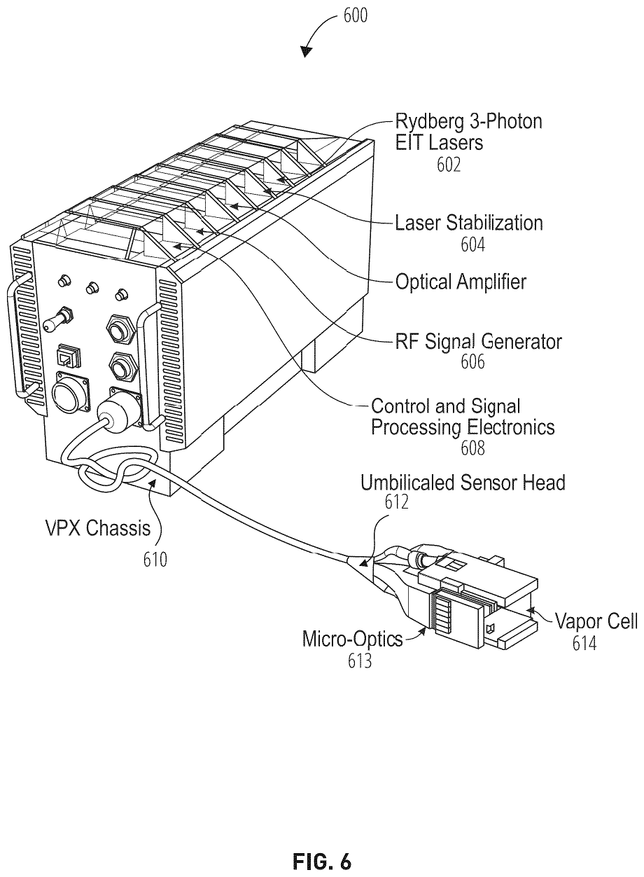

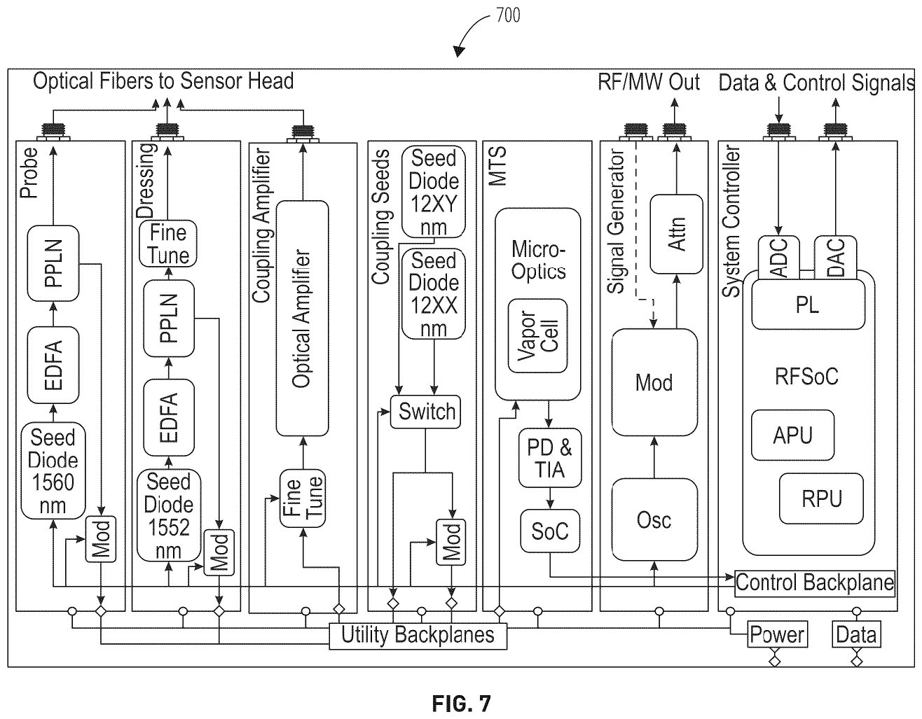

In an example, the first excitation mode and the second excitation mode can be defined by respective different optical excitation parameters comprising at least one of: an excitation beam size; a probe laser detuning; an optical power level; or an RF heterodyne power level; or combinations thereof, that differ between the first excitation mode and the second excitation mode. In an example, the optical power level of at least one of the respective laser sources is lower in the first excitation mode than in the second excitation mode. In an example, the optical excitation parameters can be controlled using a control system, such as shown in FIG. 7. In an example, the control system can be co-located with the at least two laser sources as a portion of a modular chassis arrangement, such as shown and described below in relation to FIG. 6 and FIG. 7.

At 106, in an example, the method 100 includes detecting an optical signal corresponding to fluorescence or absorption from the atomic species, the optical signal corresponding to an optical signal type associated with the established operational mode, the optical signal elicited in response to an incident RF signal falling within an RF detection bandwidth corresponding to the established operational mode.

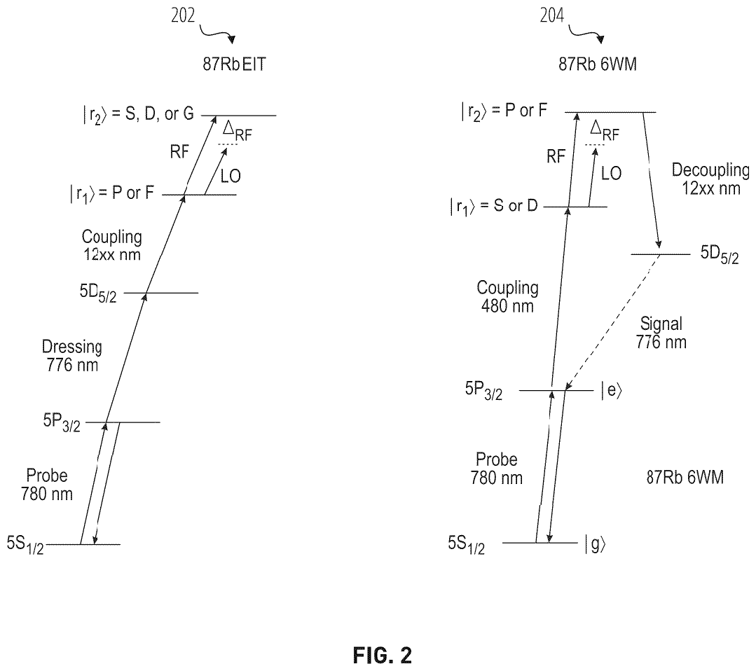

FIG. 2 illustrates Rydberg excitation schemes in an energy level diagram to detect RF fields via RF-to-optical photon transduction in accordance with various examples.

In an example, EIT levels 202 an atomic species may be used with various lasers to provide the excitation, as shown in the ⁸⁷Rb EIT energy level diagram of FIG. 2. The electromagnetically induced transparency or absorption (EIT or EIA) process is a multi-level optical excitation to a Rydberg state, selected for a resonance with an RF signal field of interest (e.g., to sense an incident RF field).

The present subject matter may include or use a probe laser beam and one or more coupling laser beams that are aligned to intersect within a vapor cell to provide multi-level optical excitation to particles (e.g., neutral or charged atoms or molecules) into a superposition of a ground state and a Rydberg state. A volume within which the laser beams intersect is referred to as a “Rydberg intersection” to emphasize its characteristic contents. The probe laser beam, dressing laser beam, and coupling laser beam wavelengths are shown for EIT levels 202 and are established according to a 3-photon EIT excitation scheme accessing P-S, F-D, and F-G Rydberg transitions.

A received RF field may be incident on the Rydberg intersection so as to split a transmission peak of the probe laser beam as it passes through the Rydberg intersection. The frequency difference (Δf) between the transmission peaks (corresponding to Autler-Townes (AT) splitting) is proportional to an amplitude of an incident RF field. The amplitude of the incident RF field may be determined from a frequency spectrum obtained by frequency sweeping the probe laser beam as it is transmitted through the Rydberg intersection.

In an example, such as using a heterodyne detection scheme to detect an optical signal corresponding to absorption, a local oscillator (LO) RF electrical signal may be mixed with an incoming RF signal to produce an intermediate frequency (IF). The probe laser beam may be tuned to a particular frequency (e.g., relative to a nominal probe laser frequency), and variations of the probe beam absorption through the Rydberg intersection may vary (e.g., in amplitude) at the intermediate frequency. Detection (e.g., with a photodiode) and processing (e.g., with a spectrum analyzer) of the probe beam provides the frequency of the incoming RF signal.

In an example, a six-wave mixing (6WM) technique may be used to address similar excitation pathways in the same atomic species as the EIT excitation structure, as shown in the ⁸⁷Rb energy level diagrams of 204.

The 6WM technique may use photons (e.g., provided by laser sources) of similar energies corresponding to wavelengths in the near-infrared and optical range, with the addition of an approximately 480 nanometer (nm) coupling laser to complete the coherent 6WM process. In the 6WM process, when a received RF field is incident on the Rydberg intersection, the decay pathway (e.g., through decoupling laser) may produce a signal photon at approximately 776 nm. In an example such as where optical filtering is used to detect an optical signal corresponding to fluorescence, the amplitude of the incident RF field may be determined by appropriately detecting (e.g., optically filtering) the signal photons at 776 nm. In this example, the amount of signal photons (e.g., intensity of the optical peak) may be proportional to the amplitude of the incident RF field.

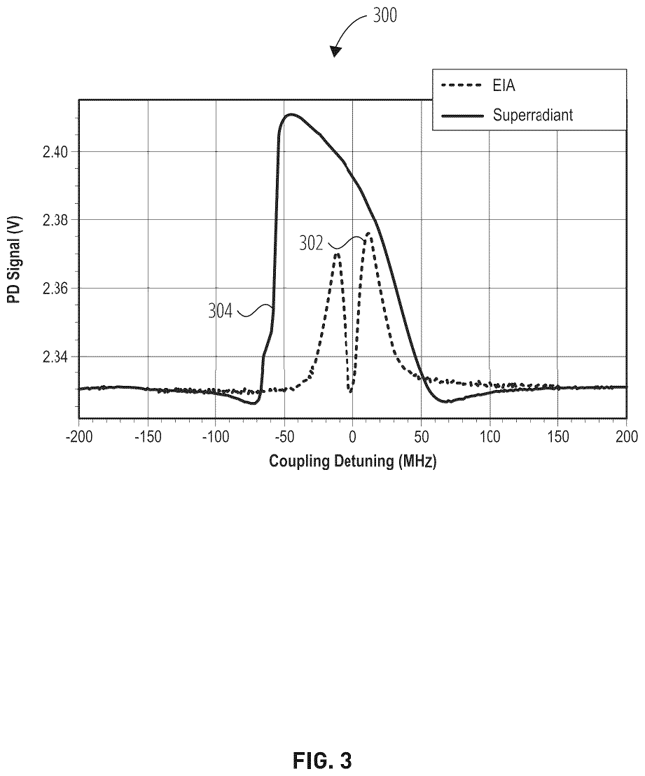

FIG. 3 illustrates a graph 300 with curves 302 and curve 304 depicting electrical photodiode signals collected during individual decay and collective decay excitation modes (respectively), as a function of coupling laser detuning from −200 to +200 MHz relative to a nominal coupling laser frequency. In an example, the continuous-wave (CW) sensing modality described using the EIT levels 202 of FIG. 2 (or similar 3-level excitation that addresses different Rydberg transitions) may be switched between narrow instantaneous bandwidth (iBW) mode and broad iBW mode by inducing collective decay in the atomic vapor. In particular, the Rydberg RF sensors may maintain a sensitivity-bandwidth product across the narrow iBW mode (EIT) and the broad iBW mode (superradiant).

The EIT process is a multi-level optical excitation to a Rydberg state. As described in FIG. 2, the multi-level optical excitation may be selected to generate a resonance with an RF signal field of interest. The EIT signal shown in curve 302 of FIG. 3 may be a result of using three (3) optical fields to excite the 42F Rydberg states, similar to the energy levels 202 shown in FIG. 2.

Collective decay behavior in atomic vapors indicates the onset of cooperative (e.g., ensemble) behavior among the atoms in the sensor. The same excitation structure (e.g., EIT levels 202) may be used in the collective decay regime as used in the individual decay regime. For collective decay in fluorescence schemes, light emission is increased due to the increased decay process (e.g., from a higher energy state to lower energy state), as opposed to the individual decay process.

In an example, tuning parameters as described in block 104 of FIG. 1 may transition a Rydberg RF sensor from a narrow bandwidth EIT excitation mode to a collective decay excitation mode, where population of and decay from the Rydberg energy level is a cooperative (e.g., ensemble) effect. As a particular example, an optical output power of the dressing laser (e.g., at 776 nm as shown in the EIT levels 202) can be increased from a first power level (e.g., 10's of micro-Watts) used with the narrow bandwidth EIT excitation mode to a second power level (e.g., 10's of milli-Watts) to transition the sensor to the collective decay excitation mode. In both modes, in this example, the probe laser absorption may be detected, and a corresponding increase in the iBW may be observed when the dressing laser output power is increased.

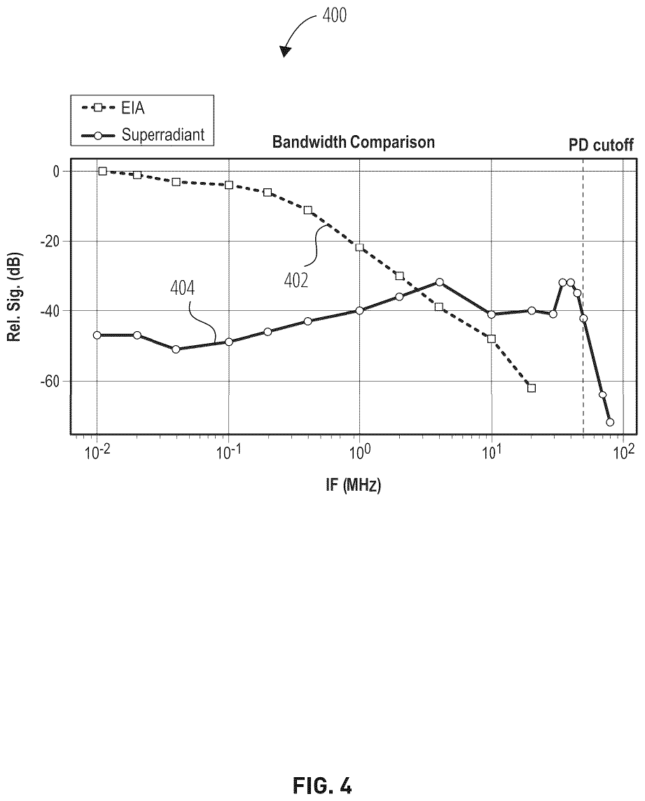

FIG. 4 illustrates a graph 400 with curves 402 and curve 404 providing a detection bandwidth comparison between EIA and collective decay detection modes across intermediate frequencies (IF) from 10⁻² to 10² MHZ. In the signal collection for FIG. 4, as in an example, an RF heterodyne detection scheme may be used. The intermediate frequency (IF) may be the difference frequency between an RF signal field of interest and an applied local oscillator (LO) RF field.

In the collective decay regime shown in curve 404, the IF bandwidth (which may roughly correspond to the broadest detection bandwidth) at the same incident RF signal strength may be extended from about 2 MHz to more than 50 MHz. As indicated in FIG. 4, instantaneous bandwidth data shown is limited by a bandwidth of the photodetector used in the data collection.

The data shown in curve 402 and curve 404 FIG. 4 show that collective decay behavior may expand individual decay-based Rydberg RF sensor instantaneous bandwidth (iBW).

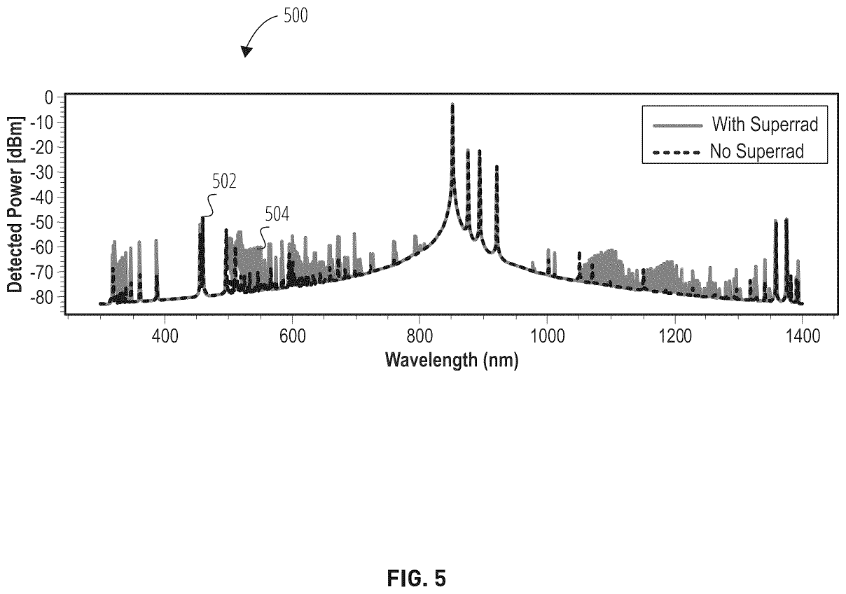

FIG. 5 illustrates a graph 500 with curves 502 and curves 504 modeling optical spectra for collective decay and individual decay regimes. As a result of the collective behavior of the atomic ensemble, wavelengths in the visible spectrum, roughly 400-700 nm, may have increased light collection (e.g., up to 15 dB at certain wavelengths). This may result in signal to noise ratio (SNR) improvements when collecting weak fluorescence light (e.g., by bandpass filtering a particular region of the fluorescence spectrum).

FIG. 6 illustrates a modular Rydberg radio frequency (RF) detection system 600 including a modular chassis containing EIT lasers 602, laser stabilization 604, RF signal generator 606, and electronics 608 for signal processing connected to an umbilicaled sensor head 612 that contains vapor cell 614 and micro optics 613. In an example, micro optics include optical structures that are compact enough to form a portion of sensor head assembly comprising the vapor cell. Note that, although the chassis 610 is shown as using componentry in the VPX set of standards, any other suitable connection type (e.g., PCIe) may be used to provide modularity for the components housed in the chassis 610.

The Rydberg RF detection system 600 may be based on modular chassis standards (e.g., VPX) that house a unified laser and electronics system, tethered to a vapor cell sensor head. The laser system may include diode lasers that are stabilized (e.g., EIT lasers 602 stabilized by electronic componentry in laser stabilization 604) to have low intensity and phase noise, e.g., using closed-loop feedback controls. The laser system may be used to excite atomic vapor to a Rydberg energy state, as described above in FIG. 2.

The umbilical sensor head 612 may comprise micro optics 613 to deliver the laser light from the laser system (e.g., using fiber optic patch cables in the umbilical cord) to the vapor cell. In an example, the micro optics 613 may further collect optical light for detection (e.g., a photodiode in the umbilicaled sensor head 612, or routed through a fiber optic cable to a photodiode within electronics 608). In an example, optical light collected at the umbilical sensor head may be delivered to the modular chassis through fiber optic cabling, e.g., for detection by a photodiode in the electronics system. In an example, a photodetector (and any associated wavelength/polarization filters/etc.) may be included in the umbilical sensor head. In this example, an electrical signal from the photodetector may be received at the modular chassis, e.g., by the electronics system, for processing.

The vapor cell may include electrical feedthrough wiring. The DC electrical wiring may be used for providing a continuously tunable electric field in the vicinity of the atomic vapor (e.g., to Stark shift the energy EIT levels 202), while RF coupling structures in the vapor cell may be used for RF heterodyne methods. As an example, heterodyne detection uses a local oscillator (LO) RF electrical signal mixed with an incoming RF signal to produce an intermediate frequency (IF). This mixing process occurs within the vapor cell, where interactions between the atoms and the RF electromagnetic field modify the optical transmission properties of the atomic vapor. A photodetector then measures these changes. The electronics system may produce RF electrical signals, perform signal processing from the vapor cell (e.g., by detecting optical or by received electrical signals produced from photodetectors in the vapor cell).

The modular (e.g., VPX) chassis architecture may facilitate precise control over optical and electrical parameters, such as (but not limited to) output laser power, tuning parameters for various lasers, closed-loop feedback setpoints and error circuitry (e.g., for laser stabilization), gain of electrical signals received from the umbilical sensor head, producing a LO RF signal, etc. The entire detection process may be occur using integrated control electronics, which may enable automated operation and real-time adjustment of detection parameters for the RF detection system.

FIG. 7 illustrates a Rydberg RF detection architecture diagram showing interconnected modules for probe, dressing, coupling amplifier, and coupling seeds, along with control systems, connected via optical fibers, RF/MW outputs, and data/control signals through utility and control backplanes.

In an example, centralized control electronics orchestrate system functionality, and a user interface with signal visualization facilitates experimentation and workflow. The system control electronics card may be based on an RF system-on-chip (RF SoC) chipset. The system control electronics card may include signal generation (RF and ancillary), ingestion of sensor output signals, and high-speed analog-to-digital (ADC) and digital-to-analog (DAC) converters. High fidelity RF signals up to ˜ 12 GHz may be generated with direct synthesis from the RFSoC and in an example, higher frequencies may use additional signal generators in the modular chassis form factor (e.g., VPX). The system control electronics card may also include integrated laser control and locking electronics. In an example, the system control electronics card may be automated using, e.g., locking software to streamline system operation and reduce user intervention.

Examples include a laser system that may have a frequency-doubled ˜ 1550 nm telecom laser architecture for probe and dressing lasers. These lasers may have the same modular line card architecture and may include componentry that allows for wavelength selection of the probe laser (e.g., 780 nm) and the RF dressing laser (e.g., 776 nm). In an example, the componentry can be removable and replaced with alternative componentry that allows for alternative wavelengths to be selected.

The present subject matter can include, use, or can be compatible with generally available telecom laser architectures, in terms of tolerating the low intensity and phase noise corresponding to such telecom laser architectures. Fine frequency tuning may provide the detuned laser fields. The coupling laser architecture may be modular. For example, the coupling laser may include seed diode lasers whose wavelengths are selected for specific RF frequencies of interest. As a particular example, sensing an incident RF field near 0 Hz (DC) through THz may be performed by using O-band telecom diode laser wavelengths. Optionally, the laser system may include a tapered amplifier or semiconductor optical amplifier stage to provide the necessary coupling optical power.

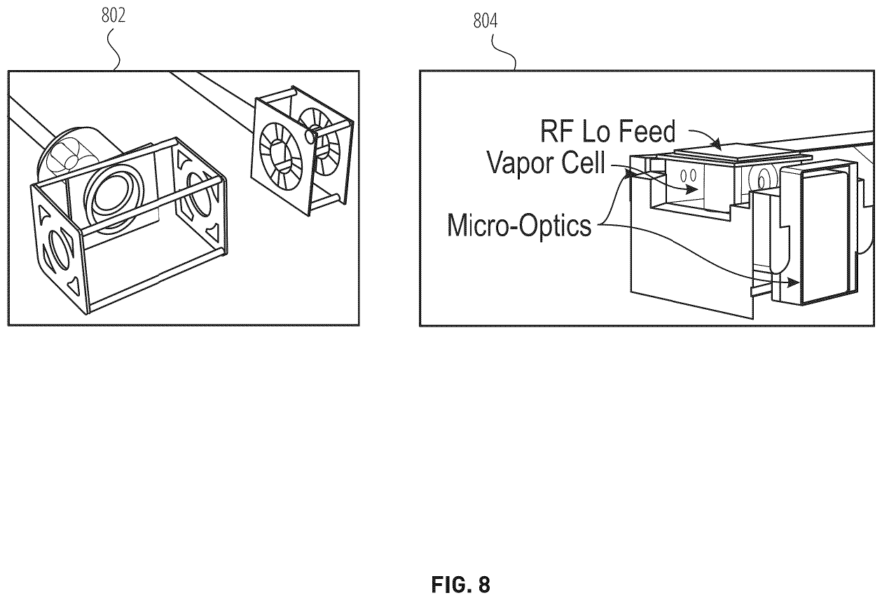

FIG. 8 illustrates vapor cell and sensor componentry. In particular, vapor cell 802 may be a vapor cell having coplanar silicon and glass electric feedthroughs for DC field sensing. In an example, a vapor cell may include an all-glass construction with thin film (e.g., Al₂O₃) and AR-coatings. The vapor cell 802 may be used, for example, in umbilical sensor head 804 that shows a 1 cc vapor cell Rydberg receiver with micro-optics and RF heterodyne electrodes. Integrated electrode structures may enable continuous Stark tuning and RF heterodyne techniques. Additional atom-RF field coupling structures not shown in FIG. 8 may be included.

Sensor heads in various examples combine a vapor cell (containing the atomic vapor, e.g., rubidium or cesium) with micro-optic systems. The micro-optic systems comprise mm-scale optical componentry that may deliver laser fields to the active sensing volume in the vapor cell. In an example, a beam geometry may be specified by the optical componentry selected for use with a particular vapor cell.

Sensor heads may be configured to mate with an umbilical cord, such as that shown in FIG. 6. In an example, a sensor head may include a vapor cell that is configured for DC field sensing, such as in FIG. 8. In an example, the sensor head may be removably configured such that a different sensor head can be used with the modular chassis. In an example, the sensor head may be removable from the umbilical cord. In an example, the sensor head may be fixed to the umbilical cord, and the umbilical cord can be un-mated from the chassis to exchange sensor heads.

Example 1 is a method for radio frequency (RF) sensing, comprising: establishing an operational mode from at least two available operational modes, the two available operational modes corresponding to different RF detection bandwidths; generating, using respective laser sources having optical excitation parameters that correspond to the established operational mode, optical excitation of an atomic species; and detecting an optical signal corresponding to fluorescence or absorption from the atomic species, the optical signal corresponding to an optical signal type associated with the established operational mode, the optical signal elicited in response to an incident RF signal falling within an RF detection bandwidth corresponding to the established operational mode.

In Example 2, the subject matter of Example 1 includes, wherein the optical excitation of the atomic species establishes a Rydberg energy state.

In Example 3, the subject matter of Examples 1-2 includes, wherein the atomic species is held in a vapor cell.

In Example 4, the subject matter of Example 3 includes, wherein the atomic species comprises rubidium or cesium.

In Example 5, the subject matter of Examples 1-4 includes, wherein the at least two available operational modes comprise: a first operational mode comprising a first excitation mode and a first optical signal type corresponding to fluorescence or absorption being produced in response to electromagnetically-induced transparency associated with the incident RF signal; or a second operational mode comprising a second excitation mode and a second optical signal type corresponding to fluorescence or absorption being produced in response to an ensemble effect in the atomic species; wherein the first optical signal type of the first excitation mode corresponds to a narrower RF signal detection bandwidth than the second optical signal type of the second excitation mode.

In Example 6, the subject matter of Example 5 includes, wherein the at least two laser sources are configured to establish the first excitation mode.

In Example 7, the subject matter of Examples 5-6 includes, wherein the at least two laser sources are configured to establish the second excitation mode.

In Example 8, the subject matter of Examples 5-7 includes, wherein the first excitation mode and the second excitation mode are defined by respective different optical excitation parameters comprising at least one of: an excitation beam size; a probe laser detuning; an optical power level; or an RF heterodyne power level; or combinations thereof, that differ between the first excitation mode and the second excitation mode.

In Example 9, the subject matter of Example 8 includes, wherein the optical power level of at least one of the respective laser sources is lower in the first excitation mode than in the second excitation mode.

In Example 10, the subject matter of Examples 8-9 includes, wherein the optical excitation parameters are controlled using a control system; and wherein the control system is co-located with the at least two laser sources as a portion of a modular chassis arrangement.

In Example 11, the subject matter of Examples 5-10 includes, wherein the ensemble effect comprises superradiance.

Example 12 is a radio frequency (RF) sensing system comprising: at least two laser sources configured to optically excite an atomic species in a vapor cell to establish a Rydberg energy state; a control system configured to: establish an operational mode from at least two available operational modes, the two available operational modes corresponding to different RF detection bandwidths; and configure optical excitation parameters of the at least two laser sources according to the established operational mode; and a detection system configured to detect a optical signal corresponding to fluorescence or absorption from the atomic species, the optical signal corresponding to an optical signal type associated with the established operational mode, the optical signal elicited in response to an incident RF signal falling within an RF detection bandwidth corresponding to the established operational mode.

In Example 13, the subject matter of Example 12 includes, wherein the at least two available operational modes comprise: a first operational mode comprising a first excitation mode and a first optical signal type corresponding to fluorescence or absorption being produced in response to electromagnetically induced transparency associated with the incident RF signal; or a second operational mode comprising a second excitation mode and a second optical signal type corresponding to fluorescence or absorption being produced in response to an ensemble effect in the atomic species; wherein the first optical signal type of the first excitation mode corresponds to a narrower RF signal detection bandwidth than the second optical signal type of the second excitation mode.

In Example 14, the subject matter of Example 13 includes, wherein the first excitation mode and the second excitation mode are defined by respective different optical excitation parameters comprising at least one of: an excitation beam size; a probe laser detuning; an optical power level; or an RF heterodyne power level; or combinations thereof, that differ between the first excitation mode and the second excitation mode.

In Example 15, the subject matter of Example 14 includes, wherein the optical power level of at least one of the respective laser sources is lower in the first excitation mode than in the second excitation mode.

In Example 16, the subject matter of Examples 12-15 includes, a modular chassis defining interfaces to respective hardware units, wherein the respective hardware units house the at least two laser sources and the control system.

In Example 17, the subject matter of Example 16 includes, an electro-optical umbilical connection between the modular chassis and a sensor head containing the vapor cell, the sensor head configured to be positioned away from the modular chassis.

In Example 18, the subject matter of Example 17 includes, wherein the vapor cell comprises: integrated electrical feedthroughs to RF coupling structures; and optical elements for excitation light delivery and optical signal light collection.

In Example 19, the subject matter of Example 18 includes, wherein the umbilical connection defines an electro-optical connector interface configured to mate with different sensor heads corresponding to different RF detection bands.

In Example 20, the subject matter of Example 19 includes, wherein the umbilical connection comprises electro-optic cabling between the modular chassis housing the at least two laser sources and the control system and a remotely located sensor head.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Other technical features and example embodiments may be readily apparent to one skilled in the art from the figures, descriptions, and claims herein.

A detailed description of one or more embodiments of the invention is provided above along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the preceding description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As used herein, a computer-readable storage medium refers, for example, to both machine-storage media and transmission media. Thus, the terms include both storage devices/media and carrier waves/modulated data signals. The terms “machine-readable medium,” “computer-readable medium” and “device-readable medium” mean the same thing and may be used interchangeably in this disclosure.

As used herein, a machine storage medium refers, for example, to a single or multiple storage devices and media (e.g., a centralized or distributed database, and associated caches and servers) that store executable instructions, routines and data. The term shall accordingly be taken to include, but not be limited to, solid-state memories, and optical and magnetic media, including memory internal or external to processors. Specific examples of machine-storage media, computer-storage media and device-storage media include non-volatile memory, including by way of example semiconductor memory devices, e.g., erasable programmable read-only memory (EPROM), electrically erasable programmable read-only memory (EEPROM), FPGA, and flash memory devices; magnetic disks such as internal hard disks and removable disks; magneto-optical disks; and CD-ROM and DVD-ROM disks. The terms “machine-storage medium,” “device-storage medium,” “computer-storage medium” mean the same thing and may be used interchangeably in this disclosure. The terms “machine-storage media,” “computer-storage media,” and “device-storage media” specifically exclude carrier waves, modulated data signals, and other such media.

As used herein, a non-transitory computer-readable storage medium refers, for example, to a tangible medium that is capable of storing, encoding, or carrying the instructions for execution by a machine.

It will also be understood that, although the terms first, second, etc. are, in some instances, used herein to describe various elements, these elements should not be limited by these terms. These terms are used only to distinguish one element from another. For example, a first tuner could be termed a second tuner, and, similarly, a second tuner could be termed a first tuner, without departing from the scope of the various described embodiments. The first tuner and the second tuner are both tuners, but they are not the same tuner.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. A method for radio frequency (RF) sensing, comprising:
establishing an operational mode from at least two available operational modes, the two available operational modes corresponding to different RF detection bandwidths;
generating, using respective laser sources having optical excitation parameters that correspond to the established operational mode, optical excitation of an atomic species; and
detecting an optical signal corresponding to fluorescence or absorption from the atomic species, the optical signal corresponding to an optical signal type associated with the established operational mode, the optical signal elicited in response to an incident RF signal falling within an RF detection bandwidth corresponding to the established operational mode.

2. The method of claim 1, wherein the optical excitation of the atomic species establishes a Rydberg energy state.

3. The method of claim 1, wherein the atomic species is held in a vapor cell.

4. The method of claim 3, wherein the atomic species comprises rubidium or cesium.

5. The method of claim 1, wherein the at least two available operational modes comprise:
a first operational mode comprising a first excitation mode and a first optical signal type corresponding to fluorescence or absorption being produced in response to electromagnetically-induced transparency associated with the incident RF signal; or
a second operational mode comprising a second excitation mode and a second optical signal type corresponding to fluorescence or absorption being produced in response to an ensemble effect in the atomic species;
wherein the first optical signal type of the first excitation mode corresponds to a narrower RF signal detection bandwidth than the second optical signal type of the second excitation mode.

6. The method of claim 5, wherein the at least two laser sources are configured to establish the first excitation mode.

7. The method of claim 5, wherein the at least two laser sources are configured to establish the second excitation mode.

8. The method of claim 5, wherein the first excitation mode and the second excitation mode are defined by respective different optical excitation parameters comprising at least one of: an excitation beam size; a probe laser detuning; an optical power level; or an RF heterodyne power level; or combinations thereof, that differ between the first excitation mode and the second excitation mode.

9. The method of claim 8, wherein the optical power level of at least one of the respective laser sources is lower in the first excitation mode than in the second excitation mode.

10. The method of claim 8, wherein the optical excitation parameters are controlled using a control system; and
wherein the control system is co-located with the at least two laser sources as a portion of a modular chassis arrangement.

11. The method of claim 5, wherein the ensemble effect comprises superradiance or ionization.

12. A radio frequency (RF) sensing system comprising:
at least two laser sources configured to optically excite an atomic species in a vapor cell to establish a Rydberg energy state;
a control system configured to:
establish an operational mode from at least two available operational modes, the two available operational modes corresponding to different RF detection bandwidths; and
configure optical excitation parameters of the at least two laser sources according to the established operational mode; and
a detection system configured to detect an optical signal corresponding to fluorescence or absorption from the atomic species, the optical signal corresponding to an optical signal type associated with the established operational mode, the optical signal elicited in response to an incident RF signal falling within an RF detection bandwidth corresponding to the established operational mode.

13. The system of claim 12, wherein the at least two available operational modes comprise:
a first operational mode comprising a first excitation mode and a first optical signal type corresponding to fluorescence or absorption being produced in response to electromagnetically induced transparency associated with the incident RF signal; or
a second operational mode comprising a second excitation mode and a second optical signal type corresponding to fluorescence or absorption being produced in response to an ensemble effect in the atomic species;
wherein the first optical signal type of the first excitation mode corresponds to a narrower RF signal detection bandwidth than the second optical signal type of the second excitation mode.

14. The system of claim 13, wherein the first excitation mode and the second excitation mode are defined by respective different optical excitation parameters comprising at least one of: an excitation beam size; a probe laser detuning; an optical power level; or an RF heterodyne power level; or combinations thereof, that differ between the first excitation mode and the second excitation mode.

15. The system of claim 14, wherein the optical power level of at least one of the respective laser sources is lower in the first excitation mode than in the second excitation mode.

16. The system of claim 12, comprising a modular chassis defining interfaces to respective hardware units, wherein the respective hardware units house the at least two laser sources and the control system.

17. The system of claim 16, comprising an electro-optical umbilical connection between the modular chassis and a sensor head containing the vapor cell, the sensor head configured to be positioned away from the modular chassis.

18. The system of claim 17, wherein the vapor cell comprises:
integrated electrical feedthroughs to RF coupling structures; and
optical elements for excitation light delivery and optical signal light collection.

19. The system of claim 18, wherein the umbilical connection defines an electro-optical connector interface configured to mate with different sensor heads corresponding to different RF detection bands.

20. The system of claim 19, wherein the umbilical connection comprises electro-optic cabling between the modular chassis housing the at least two laser sources and the control system and a remotely located sensor head.
